(19) United States
(12) Patent Application Publication
(10) Pub. No.: US 2020/0381898 A1
(43) Pub. Date: Dec. 3, 2020

(54) SEMICONDUCTOR LIGHT-EMITTING DEVICE

(71) Applicant: SONY SEMICONDUCTOR SOLUTIONS CORPORATION, KANAGAWA (JP)

(72) Inventors: TAKAYUKI KAWASUMI, KANAGAWA (JP); KOTA TOKUDA, KANAGAWA (JP)

(21) Appl. No.: 16/766,469

(22) PCT Filed: Sep. 27, 2018
(86) PCT No.: PCT/JP2018/035965

§ 371 Date: May 22, 2020

(30) Foreign Application Priority Data
Dec. 1, 2017 (JP) 2017-231828

(51) Int. Cl. H01S 5/30; H01L 33/02; H01S 5/343; H01S 5/34

(52) U.S. Cl. CPC H01S 5/3063; H01L 33/025; H01L 33/0012; H01S 5/34346; H01S 5/3408; H01S 5/34333

(57) ABSTRACT

A semiconductor light-emitting device includes a layer structure of a nitride semiconductor, and the layer structure includes an n-type semiconductor layer, a p-type semiconductor layer, and an intermediate layer. The intermediate layer includes an active layer and is provided between the n-type semiconductor layer and the p-type semiconductor layer. The layer structure includes a residual donor in a region at least included in the intermediate layer, the region being situated between the active layer and the p-type semiconductor layer. The intermediate layer includes impurities in the region between the active layer and the p-type semiconductor layer, the impurities compensating the residual donor. Further, the intermediate layer is configured such that a concentration of the impurities in the region between the active layer and the p-type semiconductor layer is higher than a concentration of the impurities in the p-type semiconductor layer.

### TECHNICAL FIELD

The present technology relates to a semiconductor light-emitting device such as a laser diode (LD) and a light emitting diode (LED).

### BACKGROUND ART

Semiconductor lasers are used in various fields. For example, for the reasons that all of the semiconductor lasers that respectively generate pieces of light of red, green, and blue that are three primary colors of light have been developed, the semiconductor lasers are expected to be applied to video display devices such as a TV and a projector, taking advantage of their characteristics such as a compact body and low power consumption.

The semiconductor optical device disclosed in Patent Literature 1 includes a laminated structure including a first compound semiconductor layer of an n type, an active layer, and a second compound semiconductor layer of a p type. The active layer includes at least 3 barrier layers and a well layer interposed among the barrier layers. The suppression of electron overflow is suppressed by appropriately designing bandgap energy values of these barrier layers (for example, refer to Patent Literature 1).

### CITATION LIST

### Patent Literature

Patent Literature 1: Japanese Patent Application Laid-open No. 2016-219587

### DISCLOSURE OF INVENTION

### Technical Problem

In particular, there is now a need for a further improvement in an output and the efficiency of semiconductor light-emitting devices using a nitride semiconductor that respectively generate blue light and green light.

An object of the present disclosure is to improve the characteristics of a semiconductor light-emitting device using a nitride semiconductor.

### Solution to Problem

A semiconductor light-emitting device according to an embodiment includes a layer structure of a nitride semiconductor, and the layer structure includes an n-type semiconductor layer, a p-type semiconductor layer, and an intermediate layer.

The intermediate layer includes an active layer and is provided between the n-type semiconductor layer and the p-type semiconductor layer.

The layer structure includes a residual donor in a region at least included in the intermediate layer, the region being situated between the active layer and the p-type semiconductor layer.

The intermediate layer includes impurities in the region between the active layer and the p-type semiconductor layer, the impurities compensating the residual donor. Further, the intermediate layer is configured such that a concentration of the impurities in the region between the active layer and the p-type semiconductor layer is higher than a concentration of the impurities in the p-type semiconductor layer.

A hole injected from the p-type semiconductor layer easily reaches the active layer via a region between the active layer and the p-type semiconductor layer since the intermediate layer includes impurities that suppress a residual donor. This results in improving the light conversion efficiency.

The p-type semiconductor layer may be a layer that includes magnesium as an acceptor.

The impurities may be at least one of carbon, iron, or zinc.

The impurities may be at least one of a Group 2 element or a Group 4 element.

The semiconductor light-emitting device may further include a substrate on which the layer structure is formed.

The substrate may be made primarily of gallium nitride, aluminum nitride, sapphire, or silicon.

The substrate may be made of gallium nitride, and a plane orientation of a principal face of the substrate may be inclined with respect to both a c axis and an m axis, the principal face of the substrate being a principal face on which the layer structure is formed.

### Advantageous Effects of Invention

As described above, the present technology makes it possible to improve the characteristics of a semiconductor light-emitting device using a nitride semiconductor.

Note that the effect described here is not necessarily limitative and may be any effect described in the present disclosure.

### BRIEF DESCRIPTION OF DRAWINGS

FIGS. 1A and B of FIG. 1 each schematically illustrate an energy band near an active layer of a semiconductor light-emitting device, where injection of a hole is prevented.

FIG. 2 schematically illustrates the energy band near the active layer in a layer structure of the semiconductor light-emitting device according to the present embodiment.

FIG. 3 is a schematic cross-sectional view of a semiconductor light-emitting device according to an embodiment.

FIG. 4 illustrates a crystal structure of a nitride semiconductor, where, for example, the principal face of crystal is one of the semipolar planes.

FIG. 5 is a graph of a result of simulating the thickness of a p-side guide layer and an operating voltage when the level of a residual donor in the p-side guide layer is changed.

FIG. 6 is a graph of a result of simulating the electrical to optical efficiency in the simulation of FIG. 5.

### MODE(S) FOR CARRYING OUT THE INVENTION

Embodiments according to the present technology will now be described below with reference to the drawings.

### 1. Outline of Present Technology

From among nitride material, and, particularly, from among AlGaInN material, magnesium (Mg) is a sole acceptor dopant material that has been put to practical use. Mg exhibits a low activation rate, and thus there is a need to perform doping with respect to about 100 times the actual carrier density. There may be a decrease in luminous efficiency if doping is heavily performed, since Mg also serves as a light-absorbing source.

In order to suppress the absorption of light due to Mg, there is a need to make the overlap between an Mg-doped layer and an optical field (a light intensity distribution in the diagram of an energy band) smaller.

Forming an Mg-doped layer to be situated a certain physical distance or more away from an active layer, is considered a specific method for this. In this case, in the production of a semiconductor light-emitting device, a region from the active layer to the Mg-doped layer (that is, a p-type semiconductor layer) is intentionally not doped with an acceptor to form an intermediate layer in the region. The intermediate layer is n-type since there exists a residual donor in the intermediate layer.

An operating voltage increases when the Mg-doped layer is physically situated a certain distance or more away from the active layer. The increase in an operating voltage occurs due to the prevention of injection of a hole from the p-type side. The ease of injecting a hole greatly depends on the distance from the electrode side to the active layer in a semiconductor layer and on the concentration of a residual donor. The residual donor originates from residual impurities or nitrogen vacancy exhibiting a donor nature, and the concentration of the residual donor varies greatly depending on, for example, the type of a substrate, the plane orientation of the substrate, and the growth condition.

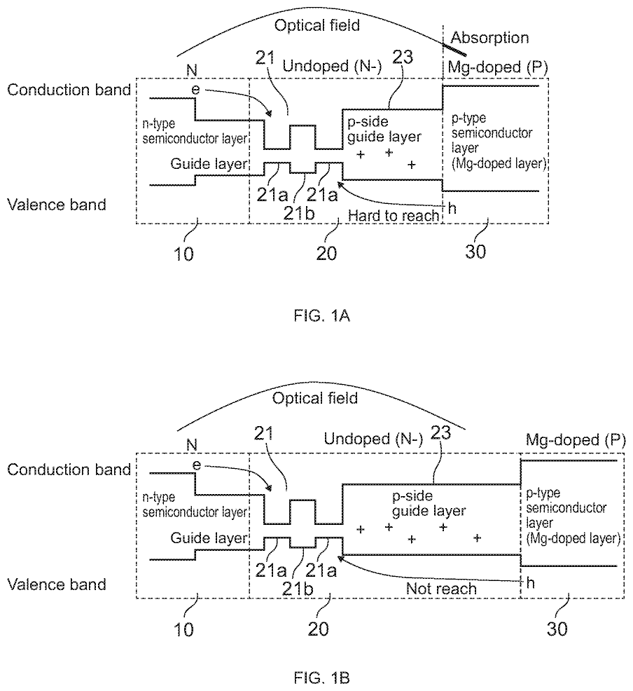

A and B of FIG. 1 each schematically illustrate an energy band near an active layer of a semiconductor light-emitting device, where injection of a hole is prevented.

As illustrated in A and B of FIG. 1, the semiconductor light-emitting device includes a layer structure. The layer structure includes, from the left, an n-type semiconductor layer 10, an intermediate layer 20 including an active layer 21, and a p-type semiconductor layer 30. In the examples illustrated in A and B of FIG. 1, the active layer 21 includes a well layer (for example, a plurality of well layers). When a plurality of well layers 21a is provided, a barrier layer 21b is provided between the well layers 21a.

The p-type semiconductor layer 30 is an Mg-doped layer that is a layer doped with Mg. For convenience of description, a region between the active layer 21 and the p-type semiconductor layer 30 is hereinafter referred to as a “p-side guide layer 23”. The intermediate layer 20 including the p-side guide layer 23 is constantly n-type since there exists a residual donor in the intermediate layer 20, as described above. The residual donor is represented by “+” in the figures.

Note that a donor (a residual donor) emits one free electron. The free electron is free to move in accordance with a bias state. Consequently, in the p-side guide layer 23, the electrical polarity of a donor that has emitted a free electron is “+”.

A of FIG. 1 indicates that there exists an overlap between the p-type semiconductor layer 30 and the optical field since the length of the p-side guide layer 23 (the distance from the active layer 21 to the p-type semiconductor layer 30) is short, which results in causing the absorption of light due to Mg.

B of FIG. 1 indicates that almost all of the holes do not reach the active layer 21 when the length of the p-side guide layer 23 described above is a certain length or more and longer than that of A of FIG. 1. Specifically, in order for a hole to reach the well layer of the active layer 21 from the p-type semiconductor layer 30, the hole has to resist repulsion of a residual donor that exhibits + polarity and is included in the p-side guide layer 23 described above to get over the p-side guide layer 23. In this case, there is a need for a large bias, and this results in increasing an operating voltage.

The reduction in the concentration of a residual donor is effective in overcoming the issues described above. In general, examples of the origin of the residual donor are residual oxygen and nitrogen vacancy, as described above. However, in order to control those origins, there is a need to significantly change the growth condition and to improve the growth method itself, and thus it is difficult to perform improvement that makes it possible to obtain satisfactory characteristics.

As a method for reducing the concentration of a residual donor, the present technology adopts a method for doping with impurities that suppress a function of the residual donor, instead of directly removing an origin of the residual donor. To suppress a function of a residual donor may be hereinafter referred to as “to compensate a residual donor”.

### 2. Embodiments

2.1) Configuration of Semiconductor Light-Emitting Device

At least one of, for example, carbon (C), iron (Fe), or zinc (Zn) is used as impurities that compensate a residual donor (hereinafter referred to as compensation impurities for convenience).

Further, instead of (or in addition to) at least one of C, Fe, or Zn described above, at least one of, for example, beryllium (Be), calcium (Ca), or barium (Ba) may be used as a Group 2 element. Furthermore, instead of (or in addition to) at least one of the elements described above, at least one of, for example, titanium (Ti) or zirconium (Zr) may be used as a Group 4 element.

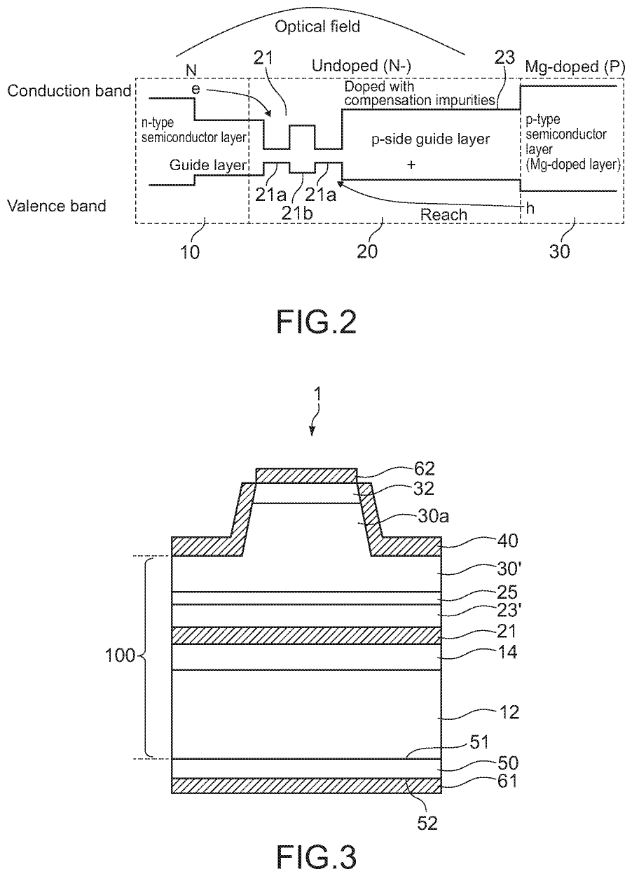

FIG. 2 schematically illustrates the energy band near the active layer 21 in the layer structure of the semiconductor light-emitting device according to the present embodiment.

According to the present embodiment, the following method is used as a method for increasing the concentration of compensation impurities in the p-side guide layer 23. In the production of the semiconductor light-emitting device, the growth condition of crystal is changed or source gas is additionally added with respect to the compensation-target region (the p-side guide layer 23). This results in forming the p-type semiconductor layer 30 and the intermediate layer 20 such that the concentration of compensation impurities in the p-side guide layer 23 is higher than that in the p-type semiconductor layer 30.

There is a possibility of the p-type semiconductor layer 30 not including compensation impurities. In other words, the concentration of compensation impurities in the p-type semiconductor layer 30 is zero in this case. However, in the production of the semiconductor light-emitting device, the p-type semiconductor layer 30 may also be doped with a small amount of compensation impurities when the intermediate layer 20 is doped with the compensation impurities, the doping of the p-type semiconductor layer 30 with the small amount of compensation impurities being unintended by the producers.

The function of a residual donor in the p-side guide layer 23 is suppressed by the p-side guide layer 23 being doped with compensation impurities. In other words, there is a reduction in the concentration of a residual donor that exhibits + polarity and applies a repulsive force to a hole. Consequently, as illustrated in FIG. 2, a hole is easily injected into the active layer 21 from the p-type semiconductor layer 30 even when the p-side guide layer 23 is thick, that is, even when the p-type semiconductor layer 30 is provided at a certain distance or more away from the active layer 21.

FIG. 3 is a schematic cross-sectional view of a semiconductor light-emitting device according to an embodiment. This semiconductor light-emitting device 1 is, for example, a nitride semiconductor laser (LD). Here, a nitride semiconductor is a compound semiconductor that includes a nitrogen (N) element, and further includes at least one element selected from the group consisting of aluminum (Al), gallium (Ga), and indium (In).

Note that the LD is an edge-face-light-exit semiconductor laser, and has a structure in which a semiconductor layer 100 is provided on a substrate 50 and placed between paired resonator edge faces.

As illustrated in FIG. 3, the LD of a nitride semiconductor is formed by the semiconductor layer 100 being formed on a side of a first principal face 51 of the substrate 50. From the side of the substrate 50, the semiconductor layer 100 includes, for example, a first cladding layer 12, a first guide layer 14, the active layer 21, a second guide layer 23′, a carrier block layer 25, a second cladding layer 30′, and a p-contact layer 32 in this order. The second guide layer 23′ corresponds to the p-side guide layer 23 described above.

The “layer structure” according to the present technology substantially corresponds to a structure from the first cladding layer 12 to the second cladding layer 30′ (or the p-contact layer 32) described above.

A first electrode layer 61 is formed on a side of a second principal face 52 of the substrate 50, the side of the second principal face 52 being opposite to the side of the first principal face 51 described above. Further, a second electrode layer 62 is formed on the surface of the p-contact layer 32. The semiconductor layer 100 includes a convex ridge 30a. Insulation coating 40 is formed over the second cladding layer 30′ and over a portion of the semiconductor layer 100 that corresponds to the ridge 30a.

For example, the substrate 50 is made primarily of material such as GaN, AlN, Al₂O₃ (sapphire), SiC, Si, or ZrO. GaN is a typical example in the present embodiment.

A principal face of crystal of a GaN substrate may be any one of a polar plane, a semipolar plane, and a nonpolar plane. The principal face is a face on which crystal glows. The polarity refers to the probability that polarization will occur and the electric field will be created, that is, the probability that the piezoelectric effect will occur. The piezoelectric effect is more likely to occur on a polar plane, and is less likely to occur on a nonpolar plane.

The polar plane can be represented by, for example, {0,0,0,1} or {0,0,0,−1} using plane indices. The semipolar plane can be represented by, for example, {2,0,−2,1}, {1,0,−1,1}, {2,0,−2,−1}, or {1,0,−1,−1}. The nonpolar plane can be represented by, for example, {1,1,−2,0} or {1,−1,0,0}. Here, it is assumed that “−” represents a bar above a figure.

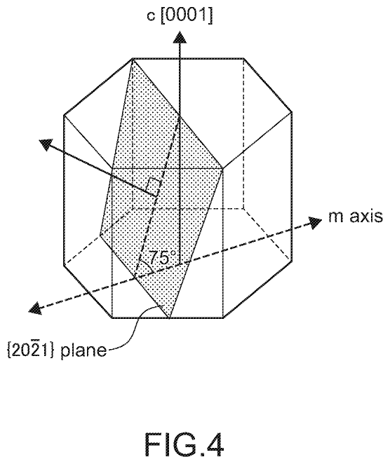

Setting {2,0,−2,1} to be a principal crystal face is highly effective in applying the present technology. As illustrated in FIG. 4, when the substrate 50 is made of GaN, the plane orientation of {2,0,−2,1} is inclined with respect to both a c axis and an m axis. Specifically, the plane {2,0,−2,1} is inclined at an angle of 75 degrees with respect to the m axis.

Note that “a plane orientation (an axis orthogonal to a plane) is inclined with respect to a specific axis” refers to a state in which the plane and the specific axis are not parallel or orthogonal to each other.

The first cladding layer 12 is formed on the first principal face 51 of the substrate 50, and includes, for example, at least one of a GaN layer, an AlGaN layer, or an AlGaInN layer that has an n-type conductivity. For example, Si may be used as a dopant for obtaining an n-type conductivity. The thickness of the first cladding layer 12 is, for example, not less than 500 nm and not greater than 3000 nm.

The first guide layer 14 is formed on the first cladding layer 12, and includes, for example, at least one of a GaN layer, an InGaN layer, or an AlGaInN layer that has an n-type conductivity. For example, Si may be used as a dopant for obtaining an n-type conductivity. Alternatively, the first guide layer 14 may be an undoped layer. The thickness of the first guide layer 14 is, for example, not less than 10 nm and not greater than 500 nm.

As described above, for example, a well layer and a barrier layer are stacked on each other to form the active layer 21 on the first guide layer 14.

The well layer includes, for example, an InGaN layer that has an n-type conductivity. Si may be used as a dopant for obtaining an n-type conductivity. Alternatively, the well layer may be an undoped layer. The thickness of the well layer is, for example, not less than 1 nm and not greater than 100 nm. In the present embodiment, a photon wavelength generated in the active layer 21 is, for example, not less than 480 nm and not greater than 550 nm.

The barrier layer includes, for example, a GaN layer, an InGaN layer, an AlGaN layer, or an AlGaInN layer that has an n-type conductivity. For example, Si may be used as a dopant for obtaining an n-type conductivity, or the barrier layer may be an undoped layer. The thickness of the barrier layer is, for example, not less than 1 nm and not greater than 100 nm. Note that the barrier layer is formed to have a bandgap not less than the largest bandgap in the well layer.

The well layer and the barrier layer are alternately provided to be adjacent to each other, where the number of well layers m satisfies m≥1, and there exists no barrier layer when m=1. In the present embodiment, m is 2 (refer to FIG. 2).

The second guide layer 23′ is formed on the active layer 21, and includes, for example, at least one of a GaN layer, an AlGaN layer, or an AlGaInN layer that has an n-type conductivity. The thickness of the second guide layer 23′ is, for example, not less than 10 nm and not greater than 500 nm. In principle, the second guide layer 23′ does not include a dopant for obtaining an n-type conductivity, although a small amount of dopant can be included. In this case, for example, Si may be used as a dopant.

The second guide layer 23′ substantially corresponds to a “region between the active layer 21 and the p-type semiconductor layer 30”, as described above. Further, the second guide layer 23′ and the active layer 21 substantially correspond to the “intermediate layer 20”. The present technology has the characteristics in that the entirety of or a portion of the second guide layer 23′ includes the compensation impurities described above and the concentration of the compensation impurities included in the entirety of or a portion of second guide layer 23′ is higher than the concentration of the compensation impurities included in the carrier block layer 25 and the second cladding layer 30′. When the compensation impurities are, for example, C, the concentration of the compensation impurities is controlled by adding C₂H₂ gas.

The carrier block layer 25 is formed on the second guide layer 23′, and includes, for example, at least one of a GaN layer, an AlGaN layer, or an AlGaInN layer that has a p-type conductivity. For example, Mg may be used as a dopant for obtaining a p-type conductivity. The thickness of the carrier block layer 25 is, for example, not less than 3 nm and not greater than 100 nm. The carrier block layer 25 can also be arranged in the second guide layer 23′ or in the second cladding layer 30′.

The second cladding layer 30′ is formed on the carrier block layer 25, and includes, for example, at least one of a GaN layer, an AlGaN layer, or an AlGaInN layer that has a p-type conductivity. For example, Mg may be used as a dopant for obtaining a p-type conductivity. The thickness of the second cladding layer 30′ is, for example, not less than 100 nm and not greater than 1000 nm.

The p-contact layer 32 is formed on the second cladding layer 30′, and includes, for example, at least one of a GaN layer, an InGaN layer, an AlGaN layer, or AlGaInN layer that has a p-type conductivity. For example, Mg may be used as a dopant for obtaining a p-type conductivity. The thickness of the p-contact layer 32 is, for example, not less than 1 nm and not greater than 100 nm.

The carrier block layer 25, the second cladding layer 30′, and the p-contact layer 32 correspond to the p-type semiconductor layer 30.

In the present embodiment, etching is performed on a lateral side of the semiconductor layer 100 to remove a region from the surface of the p-contact layer 32 to the middle of the second cladding layer 30′, and this results in forming the convex ridge 30a. Note that the region removed by performing etching may reach the second guide layer 23′ or the carrier block layer 25.

The ridge 30a is formed to extend in a direction in which light resonates (a direction vertical to the surface of the sheet of FIG. 3), and the length of the extension is, for example, not less than 50 μm and not greater than 3000 μm. Further, the width of the ridge 30a in a direction vertical to the resonating direction and the semiconductor stacking direction is, for example, not less than 0.5 μm and not greater than 100 μm.

The insulation coating 40 is formed over a portion of the semiconductor layer 100 that is exposed due to the formation of the ridge 30a. The insulation coating 40 is made of, for example, SiO₂, and the thickness of the insulation coating 40 is, for example, not less than 10 nm and not greater than 500 nm.

The first electrode layer 61 formed on the second principal face 52 of the substrate 50 is made of, for example, Ti and Al in this order from the side of the substrate 50. The thickness of a Ti layer is, for example, not less than 5 nm and not greater than 50 nm, and the thickness of an Al layer is, for example, not less than 10 nm and not greater than 300 nm.

The second electrode layer 62 formed on the p-contact layer 32 is made of, for example, Pd and Pt in this order from the side of the p-contact layer 32. The thickness of a Pd layer is, for example, not less than 5 nm and not greater than 50 nm, and the thickness of a Pt layer is, for example, not less than 10 nm and not greater than 300 nm.

2.2) Effects

As described above, in the present embodiment, a hole injected from the p-type semiconductor layer 30 easily reaches the active layer 21 via a region between the active layer 21 and the p-type semiconductor layer 30 since a portion (such as the second guide layer 23′) of the intermediate layer 20 includes compensation impurities that are impurities that compensate a residual donor. This results in improving the light conversion efficiency (the electrical to optical efficiency). In other words, specifically, it is possible to suppress the absorption of light in the p-type semiconductor layer 30 and to reduce an internal loss during operation by being able to suppress an increase in an operating voltage and to make a distance from the active layer 21 to the p-type semiconductor layer 30 longer. This results in being able to improve the light conversion efficiency and output.

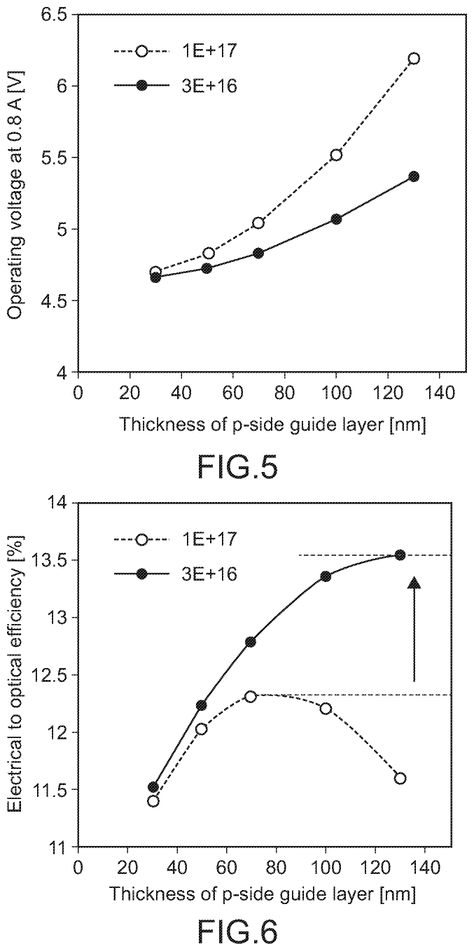

FIG. 5 is a graph of a result of simulating the thickness of the p-side guide layer 23 and an operating voltage when the level of a residual donor (the concentration of a residual donor) in the p-side guide layer 23 is changed. The operating voltage is a voltage using a constant current of 0.8 A. It is understood from the graph that there is a reduction in the operating voltage, for example, when the residual donor of a concentration of 1×10¹⁷/cm³ is compensated and the concentration of the residual donor is reduced up to 3×10¹⁶/cm³.

Further, FIG. 6 is a graph of a result of simulating the electrical to optical efficiency in the simulation of FIG. 5. If the p-side guide layer 23 is thicker (that is, the p-type semiconductor layer 30 is situated farther away from the active layer 21), the absorption of light in the p-type semiconductor layer 30 is further suppressed, but voltage increases. This results in a trade-off relationship, and there is an optimal point of the electrical to optical efficiency. If the level of a residual donor in the p-side guide layer 23 is further suppressed, the optimal point is shifted to where the p-side guide layer 23 is thicker, and the peak of the electrical to optical efficiency is improved.

As can be seen from FIG. 6, the optimal range of the thickness of the p-side guide layer 23 is between 60 nm and 200 nm, inclusive, favorably between 80 nm and 180 nm, inclusive, and more favorably between 100 nm and 160 nm, inclusive. Alternatively, it is still more favorably between 120 nm 140 nm, inclusive.

As described above, the present technology is particularly effective when the level of a residual donor is high. The present technology is effective, for example, when the level of a residual donor is made higher due to a plane orientation of the substrate 50, or when there exists a large number of defects exhibiting a donor nature due to different types of substrates being used, such as GaN growth on a Si substrate.

### 3. Modifications

The present technology is not limited to the embodiments described above, and may achieve other various embodiments. For example, an LD has been taken as an example in the embodiments described above, but the present technology is not limited to this, and is also applicable to an LED, a super luminescent diode (SLD), a semiconductor optical amplifier, and the like.

At least two of the features of the embodiments described above can also be combined.

Note that the present technology may also take the following configurations.

(1) A semiconductor light-emitting device including a layer structure of a nitride semiconductor, the layer structure including

an n-type semiconductor layer,

a p-type semiconductor layer, and

an intermediate layer that includes an active layer and is provided between the n-type semiconductor layer and the p-type semiconductor layer, in which

the layer structure includes a residual donor in a region at least included in the intermediate layer, the region being situated between the active layer and the p-type semiconductor layer,

the intermediate layer includes impurities in the region between the active layer and the p-type semiconductor layer, the impurities compensating the residual donor, and

the intermediate layer is configured such that a concentration of the impurities in the region between the active layer and the p-type semiconductor layer is higher than a concentration of the impurities in the p-type semiconductor layer.

(2) The semiconductor light-emitting device according to (1), in which

the p-type semiconductor layer is a layer that includes magnesium as an acceptor.

(3) The semiconductor light-emitting device according to (1) or (2), in which

the impurities are at least one of carbon, iron, or zinc.

(4) The semiconductor light-emitting device according to (1) or (2), in which

the impurities are at least one of a Group 2 element or a Group 4 element.

(5) The semiconductor light-emitting device according to any one of (1) to (4), further including a substrate on which the layer structure is formed, in which

the substrate is made primarily of gallium nitride, aluminum nitride, sapphire, or silicon.

(6) The semiconductor light-emitting device according to (5), in which

the substrate is made of gallium nitride, and

a plane orientation of a principal face of the substrate is inclined with respect to both a c axis and an m axis, the principal face of the substrate being a principal face on which the layer structure is formed.

### REFERENCE SIGNS LIST

1 semiconductor light-emitting device
10 n-type semiconductor layer
20 intermediate layer
21 active layer
23 p-side guide layer
30 p-type semiconductor layer
50 substrate
100 semiconductor layer

1. A semiconductor light-emitting device comprising a layer structure of a nitride semiconductor, the layer structure including
an n-type semiconductor layer,
a p-type semiconductor layer, and
an intermediate layer that includes an active layer and is provided between the n-type semiconductor layer and the p-type semiconductor layer, wherein
the layer structure includes a residual donor in a region at least included in the intermediate layer, the region being situated between the active layer and the p-type semiconductor layer,
the intermediate layer includes impurities in the region between the active layer and the p-type semiconductor layer, the impurities compensating the residual donor, and
the intermediate layer is configured such that a concentration of the impurities in the region between the active layer and the p-type semiconductor layer is higher than a concentration of the impurities in the p-type semiconductor layer.

2. The semiconductor light-emitting device according to claim 1, wherein
the p-type semiconductor layer is a layer that includes magnesium as an acceptor.

3. The semiconductor light-emitting device according to claim 1, wherein
the impurities are at least one of carbon, iron, or zinc.

4. The semiconductor light-emitting device according to claim 1, wherein
the impurities are at least one of a Group 2 element or a Group 4 element.

5. The semiconductor light-emitting device according to claim 1, further comprising a substrate on which the layer structure is formed, wherein
the substrate is made primarily of gallium nitride, aluminum nitride, sapphire, or silicon.

6. The semiconductor light-emitting device according to claim 5, wherein
the substrate is made of gallium nitride, and
a plane orientation of a principal face of the substrate is inclined with respect to both a c axis and an m axis, the principal face of the substrate being a principal face on which the layer structure is formed.
